(19) United States
(12) Patent Application Publication
(10) Pub. No.: US 2026/0162471 A1
(43) Pub. Date: Jun. 11, 2026

(54) BATTERY MANAGEMENT SYSTEM

(71) Applicant: TOYOTA JIDOSHA KABUSHIKI KAISHA, Toyota-shi (JP)

(72) Inventor: Nobuyasu HAGA, Seto-shi (JP)

(73) Assignee: TOYOTA JIDOSHA KABUSHIKI KAISHA, Toyota-shi (JP)

(21) Appl. No.: 19/398,305

(22) Filed: Nov. 24, 2025

(30) Foreign Application Priority Data
Dec. 11, 2024 (JP) 2024-216460

(51) Int. Cl. G07C 5/04; B60R 16/033; G01R 31/00; G01R 31/374; G01R 31/3835; G07C 5/00; H01M 10/42

(52) U.S. Cl. CPC G07C 5/04; B60R 16/033; G01R 31/006; G01R 31/374; G01R 31/3835; H01M 10/425; G07C 5/008; H01M 2010/4271; H01M 2220/20

(57) ABSTRACT

A battery management system for determining a state of an in-vehicle battery based on a start-up voltage of an in-vehicle battery and a predetermined voltage threshold at the time of start-up of the vehicle, comprising: a collection unit that collects vehicle data including a start-up voltage from a plurality of vehicles in the market, respectively; and an updating unit that updates the voltage threshold based on vehicle data collected from vehicles in the market.

### CROSS-REFERENCE TO RELATED APPLICATION

This application claims priority to Japanese Patent Application No. 2024-216460

filed on Dec. 11, 2024. The disclosure of the above-identified application, including the specification, drawings, and claims, is incorporated by reference herein in its entirety.

### BACKGROUND

### 1. Technical Field

The present disclosure relates to a system that manages a battery mounted on a vehicle.

### 2. Description of Related Art

Japanese Unexamined Patent Application Publication No. 2024-040667 (JP 2024-040667 A) discloses a battery management system that detects a state of an in-vehicle battery using both a voltage of the in-vehicle battery at the time of start-up of the vehicle and a charge/discharge amount of the in-vehicle battery. In this battery management system, it is possible to accurately detect a state of an in-vehicle battery such as temporary overdischarge or deterioration while suppressing the effect of an error in the voltage and the charge/discharge amount of the in-vehicle battery.

### SUMMARY

In the battery management system described in JP 2024-040667 A, the threshold that is used to determine the temporary overdischarge or deterioration of the in-vehicle battery is set using a data map prepared in advance or the like. Therefore, the actual data trend of vehicles in the market is not taken into consideration. Therefore, the method of determining temporary overdischarge and deterioration of the in-vehicle battery described in JP 2024-040667 A still has an issue in terms of determination accuracy.

The present disclosure has been made in view of the above issue, and an object of the present disclosure is to provide a battery management system capable of improving the accuracy of determining temporary overdischarge or deterioration of an in-vehicle battery in consideration of the actual data trend of vehicles in the market.

In order to address the above issue, an aspect of the present disclosure provides a battery management system that determines a state of an in-vehicle battery based on a start-up voltage of the in-vehicle battery at a time of start-up of a vehicle and a predetermined voltage threshold, the battery management system including:
a collection unit that collects vehicle data including the start-up voltage from a plurality of vehicles in a market; and
an updating unit that updates the voltage threshold based on the vehicle data collected from the vehicles in the market.

According to the battery management system of the present disclosure, the voltage threshold for determining the state of the in-vehicle battery takes into consideration the actual data trend of vehicles in the market. Therefore, it is possible to improve the accuracy of determining temporary overdischarge, deterioration, and the like of the in-vehicle battery.

### BRIEF DESCRIPTION OF THE DRAWINGS

Features, advantages, and technical and industrial significance of exemplary

embodiments of the disclosure will be described below with reference to the accompanying drawings, in which like signs denote like elements, and wherein:

FIG. 1 is a schematic configuration diagram of a battery management system according to an embodiment of the present disclosure;

FIG. 2A is a process flowchart of voltage-threshold update control performed by the battery management system;

FIG. 2B is a process flowchart of voltage-threshold update control performed by the battery management system;

FIG. 3 is an image diagram of the data-frequency profile of the corrected start-up voltage; and

FIG. 4 is a diagram for explaining a voltage threshold updating method using the quartile deviation method.

### DETAILED DESCRIPTION OF EMBODIMENTS

The logic for detecting temporary over-discharge, deterioration, or the like,

which is a cause of the rise of the in-vehicle battery, determines the change in the voltage at the time of starting of the vehicle. However, the voltage thresholds used for this determination vary depending on the hardware configuration of the vehicle (ECU system, battery mounting position, wiring configuration, and the like), and therefore need to be set for each type of vehicle. Further, it is difficult to obtain an accurate value from a complicated hard configuration of the vehicle by calculation on a desk, and it is desirable to set the voltage threshold based on actual vehicle data. Therefore, the battery management system of the present disclosure proposes a logic for suppressing voltage fluctuation factors and noise and bias and automatically setting an accurate voltage threshold on a server.

Hereinafter, an embodiment of the present disclosure will be described in detail with reference to the drawings.

### Embodiment

### Configuration

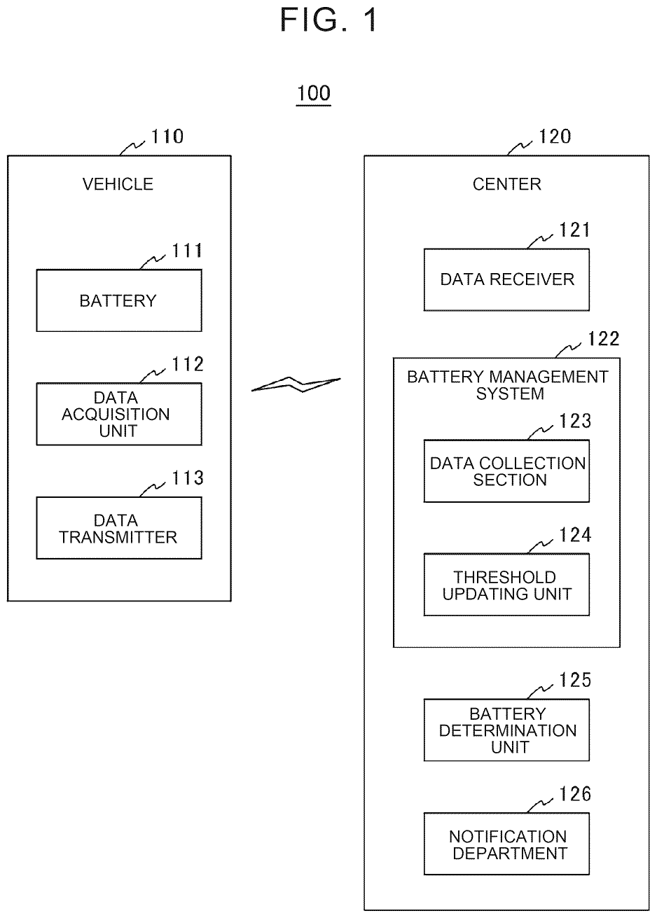

FIG. 1 is a block diagram illustrating a schematic configuration of a vehicle

communication system 100 including a battery management system 122 according to an embodiment of the present disclosure. The vehicle communication system 100 illustrated in FIG. 1 includes a vehicle 110 and a center 120 in a configuration.

### Vehicle

The vehicle 110 is communicably connected to the center 120. The vehicle 110

is, for example, an automobile or the like, and includes at least a battery 111, a data acquisition unit 112, and a data transmission unit 113. In the example of FIG. 1, only one vehicle 110 is shown that is communicably connected to the center 120, but actually, a plurality of vehicles 110 are communicably connected to the center 120.

The battery 111 is a secondary battery configured to be chargeable and dischargeable, such as a lithium-ion battery or a lead-acid battery. As the battery 111, an in-vehicle battery such as an auxiliary battery can be exemplified. The battery 111 is charged by a generator (not shown) such as an alternator, and can supply (discharge) electric power stored therein to an accessory, equipment, or the like (not shown) mounted on the vehicle 110.

The data acquisition unit 112 is a configuration for acquiring vehicle data when the vehicle 110 starts up with the ignition turned ON. The vehicle data includes information on the vehicle 110 (hereinafter, referred to as “vehicle information”) and information on the battery 111 (hereinafter, referred to as “battery information”). The vehicle data includes at least a travel distance (ODO) of the vehicle 110 and a parking time (a time from stopping when the ignition is continuously turned OFF to starting). The battery data includes at least a voltage of the battery 111 when the vehicle 110 is activated (hereinafter referred to as “activation voltage”), a current, a temperature, and a power storage rate (SOC: State Of Charge).

The data transmission unit 113 has a function of controlling communication between the vehicle 110 and the center 120. The data transmission unit 113 transmits the vehicle data acquired by the data acquisition unit 112 to the center 120. Typically, the data transmission unit 113 transmits its own vehicle data to the center 120 when the vehicle 110 is activated (when ignition ON and trip starts). The data transmission unit 113 is realized by, for example, a data communication module (DCM).

### Center

The center 120 is communicably connected to the vehicle 110. The center 120

is, for example, a server on the cloud, and includes at least a data reception unit 121, a battery management system 122, a battery determination unit 125, and a notification unit 126.

The data reception unit 121 has a function of controlling communication between the center 120 and the plurality of vehicles 110. The data reception unit 121 can receive a plurality of vehicle data transmitted from a plurality of vehicles 110. The vehicle data received by the data reception unit 121 each time is stored in, for example, a storage unit (not shown).

The battery management system 122 is a system for managing the battery 111 mounted on the vehicle 110. Characteristically, the battery management system 122 of the present embodiment performs a process of updating a voltage threshold value for determining a specific state such as a temporary over-discharge state or a deterioration state of the battery 111, which is a cause of battery rise. The battery management system 122 includes a data collection unit 123 and a threshold updating unit 124.

The data collection unit 123 collects, for each trip, vehicle data of the vehicle 110 to be controlled among the plurality of vehicle data acquired by the data reception unit 121. The vehicle 110 to be controlled may be the vehicle 110 to which the same voltage threshold value can be applied with respect to the determination of the specific state of the battery 111, and may be, for example, the vehicle 110 of the same vehicle type in which the same battery 111 is mounted. Then, the data collection unit 123 accumulates the start-up voltage included in the collected vehicle data of the vehicle 110 to be controlled until the voltage threshold is updated in accordance with a predetermined condition (sufficient vehicle data is collected). Processing related to collection and accumulation performed by the data collection unit 123 will be described later.

The threshold updating unit 124 updates (corrects) the voltage threshold used for determining the specific state of the battery 111 based on the information on the start-up voltage accumulated by the data collection unit 123. In order to set the voltage thresholds for determining the particular status of the battery 111, the power-on voltage applied to ECU device (e.g., the main ECU) is required. However, the starting-up voltage of ECU system depends on the specifications of ECU system, the diverting of the plurality of vehicle loads mounted on the vehicle 110 and the afterloading equipment, the wiring structure between the battery 111 and ECU system, and the like. Therefore, it is difficult to calculate an accurate start-up voltage by desktop calculation. Therefore, the threshold updating unit 124 automatically updates the voltage threshold used for the determination of the specific state of the battery 111 based on the vehicle data in consideration of the variation including the actual post-installation equipment acquired from the vehicle 110 actually used in the market. The voltage threshold updating process performed by the threshold updating unit 124 will be described later.

The battery determination unit 125 is configured to determine the state of the battery 111 using the voltage threshold updated by the threshold updating unit 124 or the conventional voltage threshold. As the state of the battery 111 determined by the battery determination unit 125, a specific state such as a state in which the battery 111 is temporarily over-discharged and a state in which the battery 111 is deteriorated due to aging or the like can be exemplified.

The notification unit 126 is configured to perform appropriate notification according to the state of the battery 111 determined by the battery determination unit 125. This notification is preferably made when the battery 111 is in a temporarily over-discharged state or when the battery 111 is in a deteriorated state. Examples of the notification destination include the vehicle 110 and a portable terminal such as a user or a driver of the vehicle 110.

### Control

Next, the control performed by the battery management system 122 according

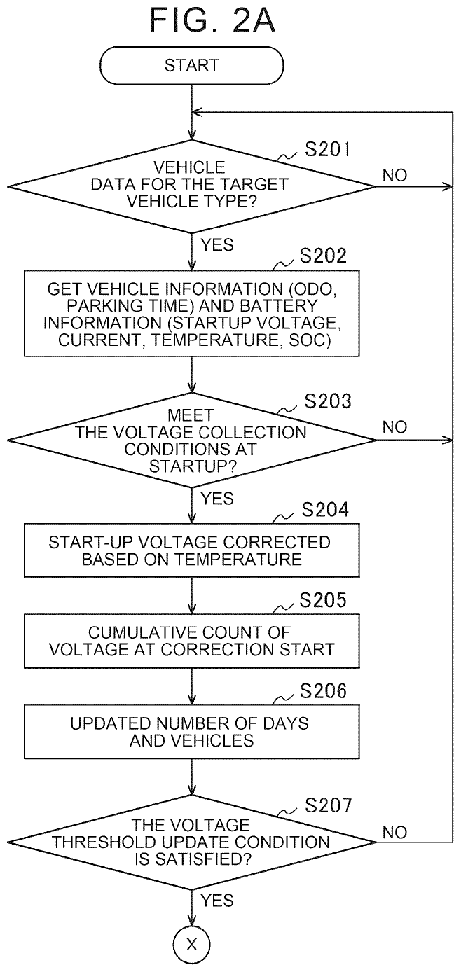

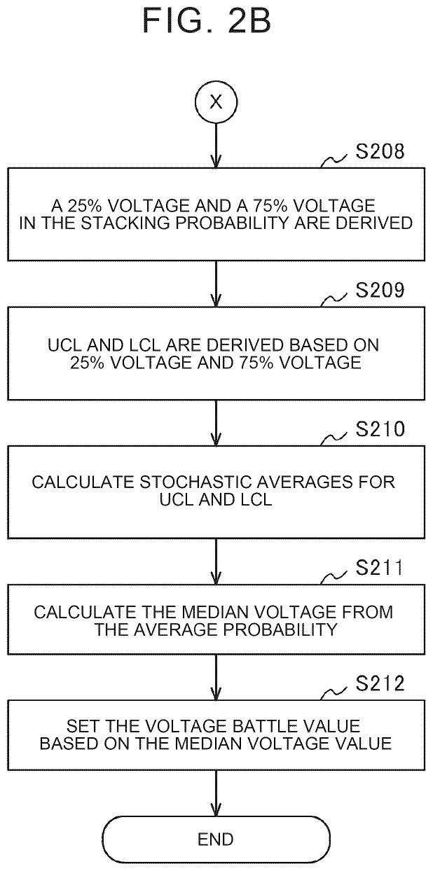

to the present embodiment will be described with reference to FIGS. 2A and 2B. FIGS, 2A and 2B are flowcharts for describing the steps of the voltage-threshold updating control executed by the respective components of the battery management system 122. The process of FIG. 2A and the process of FIG. 2B are connected by a coupler X.

The voltage-threshold updating control shown in FIGS. 2A and 2B is started, for example, when the vehicles 110 are shipped (offline) to the marketplace.

### S201

The data collection unit 123 determines whether or not there is vehicle data of a vehicle type to be controlled among the plurality of vehicle data received from the plurality of vehicles 110 by the data reception unit 121. This determination may be made each time the data reception unit 121 receives new vehicle data from the vehicle 110, or may be made at predetermined intervals.

When the data collection unit 123 determines that there is vehicle data of the vehicle type to be controlled in the received data of the data reception unit 121 (S201, Yes), the process proceeds to S202.

### S202

The data collection unit 123 acquires vehicle information and battery information of a vehicle type to be controlled from the vehicle data. Specifically, the data collection unit 123 acquires the travel distance (ODO) and the parking time as the vehicle information, and acquires the start-up voltage, the current, the temperature, and the power storage rate (SOC) as the battery information. The storage rate can be calculated on the basis of an open-circuit voltage (OCV: Open Circuit Voltage) which is a voltage of the battery 111 in an unloaded condition and a current integrated value. When the power storage rate can be directly acquired from a SOC sensor or the like, the power storage rate may be used.

When the vehicle information and the battery information of the vehicle type to be controlled are acquired by the data collection unit 123, the process proceeds to S203.

### S203

The data collection unit 123 determines whether or not a predetermined

condition (hereinafter, referred to as “collection condition”) for collecting the startup-time-voltage acquired by S202 as statistical data is satisfied. This collection condition is determined based on the travel distance (ODO) and the parking time of the vehicle 110 and the power storage rate (SOC) of the battery 111 as follows.

The first collection condition is that the travel distance (ODO) of the vehicles 110 is within a predetermined range. This first collection condition is provided to exclude the effect of degradation of the battery 111, which is one of the factors that fluctuate the start-up voltage. Since the deterioration of the battery 111 proceeds over a relatively long period of time, the deterioration state is suppressed by acquiring vehicle data immediately after delivery. Therefore, as the predetermined range, for example, a range such as 10 km<travel distance<1000 km can be set.

The second collection condition is that the parking time of the vehicle 110 is equal to or longer than a predetermined time. This second collection condition is provided to exclude the influence of the polarization of the battery 111, which is one of the factors that fluctuate the start-up voltage. The start-up voltage immediately after charging or discharging of the battery 111 is influenced by the polarization due to the concentration distribution inside the battery 111. Since the influence of the polarization gradually decreases according to the length of the standing time, the polarization state is suppressed by increasing the parking time until immediately before the vehicle 110 is activated. Therefore, as the predetermined time, for example, a time such as parking time>12 hours can be set.

The third collection condition is that the battery 111 has a power storage rate (SOC) equal to or greater than a predetermined value. This third collection condition is provided in order to exclude the influence of the storage rate of the battery 111, which is one of the factors that fluctuate the start-up voltage. Since the resistance and the open-circuit voltage (OCV) vary depending on the storage rate of the battery 111, the voltage at startup is affected by the storage rate. Normally, it is defined as a normal state that the auxiliary battery of the vehicle 110 or the like is maintained in a high storage rate state by continuous charging. Therefore, the influence of the storage rate is suppressed by using the start-up voltage when the storage rate of the battery 111 is high. Therefore, as the predetermined value, for example, a value such as a power storage rate≥80% can be set.

Note that, in order to consider the effect of the resistivity that varies depending on the temperature, the power storage rate (SOC) of the battery 111 acquired from the vehicle 110 may be corrected by Equation [1] below. Here, the resistance (25° C.) is a resistance at 25° C. in the wiring path from the battery 111 to ECU system. The temperature resistance ratio is a ratio for obtaining the resistance variation due to the actual temperature in the vehicle 110.

$$Corrected storage rate = storage rate ( OCV ) - current \times temperature resistance ratio \times resistance ( 25 °C ) \qquad [ 1 ]$$

When the data collection unit 123 satisfies all of the first collection condition,

the second collection condition, and the third collection condition, it is determined that the start-up voltage collection condition is satisfied (S203, Yes), and the process proceeds to S204. On the other hand, when the data collection unit 123 does not satisfy any one of the first collection condition, the second collection condition, and the third collection condition, it is determined that the collection condition at startup is not satisfied (S203, No), and the process proceeds to S201.

### S204

The data collection unit 123 corrects the activation time voltage obtained by S202 based on the temperature of the battery 111. This correction is performed in order to exclude the influence of the temperature, which is one of the factors that fluctuate the start-up voltage. Since the wiring resistance and the like vary depending on the temperature, the start-up voltage is affected by the temperature. Therefore, the influence of the temperature is excluded by correcting the start-up voltage using the temperature information of the battery 111 acquired simultaneously with the start-up voltage. The corrected start-up voltage (hereinafter referred to as “corrected start-up voltage”) is calculated as follows. For example, it can be calculated by the following equation [2] on the basis of the start-up voltage, the current, and the temperature of the battery 111 (before correction) obtained by the above S202 and the resistance (25° C.) and the temperature resistance ratio which are the above-mentioned constants.

$$Voltage at correction start = Open circuit voltage - current \times temperature resistance ratio \times resistance ( 25 °C ) \qquad [ 2 ]$$

The above-described resistance (25° C.) is a fixed value determined at the time of design of the vehicle 110. Therefore, the information of the resistance (25° C.) may be stored in advance by the data collection unit 123 in a storage unit (not shown) or the like the resistance (25° C.) for each vehicle type, or each vehicle 110 may be included in the vehicle data and transmitted to the center 120. Further, as the above-described information on the temperature resistance ratio, it can be exemplified that the data collection unit 123 holds the temperature resistance ratio for each vehicle type in advance in the storage unit or the like in the form of a data map or the like.

When the start-up voltage is corrected based on the temperature of the battery 111 by the data collection unit 123, the process proceeds to S205.

### S205

The data collection unit 123 generates the frequency of the correction start-up

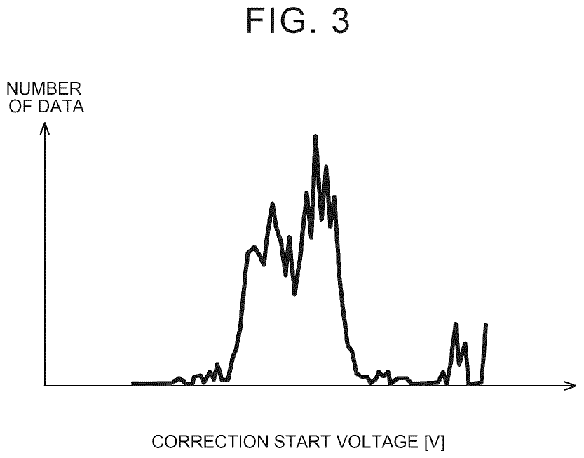

voltage obtained by the correction of S204. More specifically, the data collection unit 123 cumulatively counts the correction start-up voltage as 1 data. FIG. 3 shows an image of the data frequency distribution accumulated by the cumulative counting of the corrected start-up voltage. It is to be noted that the voltage segment to be counted may be an arbitrary range-width (for example, 0.1 V or 0.5 V). For example, when the corrected start-up voltage is 12.6 V, 12.5 V will increment 13.0 V voltage segment by one.

When the correction-start-up-time-voltage is cumulatively counted by the data collection unit 123, the process proceeds to S206.

### S206

The data collection unit 123 updates the number of days elapsed and the number

of vehicles. The number of days elapsed is information representing the number of days that have elapsed since the time when the vehicle data was acquired for the first time from the vehicle 110 in the above-described S201 (service-start). The number of vehicles is the number of vehicles 110 that have been able to acquire the vehicle data satisfying the conditions for collecting the startup voltage in the above-described S203. The number of elapsed days can be measured using a clock function (not shown) included in the data collection unit 123. The number of vehicles is incremented by one every time the corrected start-up-time-voltage is counted in S205.

When the number of days elapsed and the number of vehicles have been updated by the data collection unit 123, the process proceeds to S207.

When a plurality of pieces of vehicle data of the target vehicle type are acquired in S201 process, S206 process is performed from S202 for each of the plurality of pieces of vehicle data.

### S207

The threshold updating unit 124 determines whether or not the number of days elapsed and the number of vehicles updated in the above S206 satisfy a predetermined condition for updating the voltage threshold (hereinafter referred to as “update condition”). The update condition is determined based on the number of days elapsed and the number of vehicles as follows.

The first update condition is that the number of elapsed days is equal to or greater than a predetermined number of days. The second update condition is that the number of vehicles is equal to or greater than a predetermined number. The first update condition and the second update condition are provided to exclude the influence of data noise due to noise or bias of the collected start-up voltage, which is one of the factors that fluctuate the start-up voltage. After a sufficient number of start-up voltages in a normal state of the vehicle 110 are collected, a quartile deviation method described later is applied, and a median value is obtained to obtain a reference voltage value from which noise and deviation are suppressed, thereby suppressing data noise. As the number of days elapsed and the number of vehicles used for determination as a sufficient number, for example, values such as the number of days elapsed≥20 days and the number of vehicles≥200 days, the number of days elapsed≥60 days and the number of vehicles≥30 days can be set.

When the threshold updating unit 124 satisfies all of the first update condition and the second update condition, it is determined that the update condition of the voltage threshold is satisfied (S207, Yes), and the process proceeds to S208. On the other hand, when the threshold updating unit 124 does not satisfy any one of the first update condition and the second update condition, it is determined that the update condition of the voltage threshold is not satisfied (S207, No), and the process proceeds to S201.

### S208

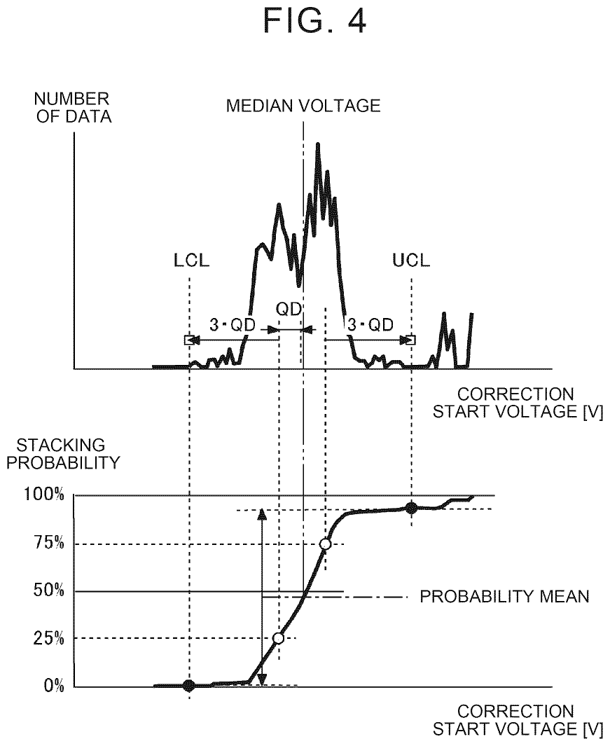

The threshold updating unit 124 creates a stacking probability line in which the ratio of the number of data in each segment to the total number of data is stacked in the order of the voltages, with the total number of data of the correction start-up voltage being 100%, based on the correction start-up voltage cumulatively counted in the above S205. The image of this stacking probability line is shown in the lower part of FIG. 4. Then, the threshold updating unit 124 derives a correction start-up voltage (25% voltage) having a probability of 25% in the stacking probability line and a correction start-up voltage (75% voltage) having a probability of 75%. An image (open circles in the drawing) of the 25% voltage and 75% voltage of the corrected start-up voltage is shown in the lower side of FIG. 4.

When the threshold updating unit 124 derives a voltage of 25% and a voltage of 75% of the corrected start-up voltage in the stacked probability line, the process proceeds to S209.

### S209

The threshold updating unit 124 derives the upper limit management limit UCL (Upper Control Limit) and the lower limit management limit LCL (Lower Control Limit) of the correction start voltage based on the 25% voltage and the 75% voltage of the correction start voltage derived in the above S208. The upper limit management limit UCL and the lower limit management limit LCL are calculated by the following equations [3], [4], and [5] using a quartile deviation QD (quartile deviation) based on the quartile deviation method. An image of the upper limit management limit UCL and the lower limit management limit LCL (open squares in the drawing) is shown in the upper side of FIG. 4.

$$Quartile deviation QD = ( 25 \% voltage + 75 \% voltage ) / 2 \qquad [ 3 ]$$

$$Upper limit management limit UCL = 75 \% voltage + 3 \times quartile deviation QD \qquad [ 4 ]$$

$$Lower limit management limit LCL = 25 \% voltage - 3 \times quartile deviation QD \qquad [ 5 ]$$

When the upper limit management limit UCL and the lower limit management limit LCL are derived by the threshold updating unit 124, the process proceeds to S210.

### S210

The threshold updating unit 124 calculates a probability-average of the upper

limit management limit UCL and the lower limit management limit LCL derived by the above S209. The probability average value is an average value of the stacking probability corresponding to the upper limit management limit UCL and the stacking probability corresponding to the lower limit management limit LCL. An image of the stacking probability corresponding to the upper limit management limit UCL and the stacking probability corresponding to the lower limit management limit LCL (a black circle in the drawing) and an image of the probability mean (a dashed-dotted line in the drawing) are shown in the lower side of FIG. 4.

When the threshold updating unit 124 calculates a probability mean between the upper limit management limit UCL and the lower limit management limit LCL, the process proceeds to S211.

### S211

The threshold updating unit 124 calculates the voltage median value of the corrected start-up voltage based on the probability-average value of the upper limit management limit UCL and the lower limit management limit LCL calculated by the above S210. This voltage median value is a value of the correction start-up voltage corresponding to the probability average value, and becomes a voltage value where the dashed-dotted line of the probability average value and the stacking probability line (solid line) on the lower side of FIG. 4 intersect.

When the median voltage of the corrected start-up voltage is calculated by the threshold updating unit 124, the process proceeds to S212.

### S212

The threshold updating unit 124 calculates and sets a new voltage threshold

based on the voltage median value of the corrected start-up voltage calculated by the above-described S211. This voltage threshold value is a voltage value that is a reference value for determining a specific state of the battery 111, and is calculated by adding a predetermined margin to the voltage median value. This margin is set for the purpose of improving the efficiency and accuracy of the determination, such as suppressing the battery determination unit 125 excessively determining the specific state of the battery 111. As an example, a value obtained by multiplying the median voltage by a predetermined factor (for example, 0.3) may be used as a voltage threshold, or a value obtained by subtracting a predetermined constant (for example, 0.3 V) from the median voltage may be used as a voltage threshold.

Note that the above-described voltage threshold setting process (S212 from S208) by the threshold updating unit 124 is executed only once after the data collection process (S207 from S201) by the data collection unit 123 is completed.

When a new voltage threshold is calculated and set by the threshold updating unit 124, this voltage threshold updating control ends.

By the process of the threshold updating unit 124, the start-up voltage in the region above the upper limit management limit UCL and the start-up voltage in the region below the lower limit management limit LCL are respectively removed. Further, by calculating the reference value for determining the specific state of the battery 111 from the median voltage value, the influence of the bias of the data can be reduced.

### Application Example

When unexpected deviations occur in a plurality of start-up voltages acquired from the vehicle 110, it is conceivable to set a fail-safe value as a voltage threshold of the start-up voltage. In this case, the fail-safe value may be set to a low voltage value at which the logic of the battery determination unit 125 does not determine a specific state such as a temporary over-discharge state and a deterioration state of the battery 111. As a processing condition (fail-safe processing condition) for setting the low voltage value, the following contents in the data frequency distribution of the correction start-up voltage can be exemplified.
The ratio of the maximum voltage of the distribution is equal to or larger than a predetermined value P1 (e.g., 5%).
The data ratio of the smallest voltage of the distribution is equal to or more than a predetermined value P1 (for example, 5%).
The ratio of the upper area above the upper limit management limit UCL is equal to or greater than a predetermined P2 (e.g., 10%).
The data ratio of the lower area than the lower limit management limit LCL is equal to or greater than a predetermined P2 (e.g., 10%).
The upper limit management limit UCL is greater than the maximum (UCL>Vmax).
Lower limit management limit LCL is lower than the minimum (LCL<Vmin)
Quartile deviation QD is greater than the highest possible (QD>QDmax).

In addition to the above-described method, fail-safe processing may be performed using an index representing a distribution shape such as kurtosis or skewness.

### Operations and Effects

As described above, in the battery management system 122 according to the embodiment of the present disclosure, it is desirable that the voltage threshold value of the start-up voltage is set based on actual vehicle data. In view of this, prior to LO of the vehicle 110, voltage thresholds (assumed numbers) are set based on the hardware specifications and the limited vehicle data, and the voltage thresholds are automatically adjusted from the market data after the line-off of the vehicle 110.

This process allows the logic to determine the specific state of the battery 111 to set the correct voltage threshold taking into account the actual data trends of the vehicle 110 in the market. Therefore, it is possible to improve the determination accuracy of the temporary overdischarge, deterioration, and the like of the battery 111.

Further, since the battery management system 122 automatically sets (adjusts) the voltage threshold based on the vehicle data, it is possible to reduce the number of man-hours for the operator to manually update the voltage threshold.

In addition, a start-up voltage in a normal state excluding a variation factor (temperature, storage rate (SOC) state, degradation state, polarization after charging/discharging, variation in battery performance, post-addition equipment, and data noise) of the start-up voltage in the market data after the offline of the vehicle 110 is acquired. Therefore, the correct voltage threshold can be updated and set.

The battery management system of the present disclosure can be used, for example, for estimating a discharge amount of a battery mounted in a vehicle.

What is claimed is:

1. A battery management system that determines a state of an in-vehicle battery based on a start-up voltage of the in-vehicle battery at a time of start-up of a vehicle and a predetermined voltage threshold, the battery management system comprising:
a collection unit that collects vehicle data including the start-up voltage from a plurality of vehicles in a market; and
an updating unit that updates the voltage threshold based on the vehicle data collected from the vehicles in the market.

2. The battery management system according to claim 1, wherein:
the vehicle data further include a travel distance of the vehicle, a parking time from a stop to a start-up of the vehicle, and a power storage rate of the in-vehicle battery; and
the collection unit accumulates the start-up voltage when the travel distance, the parking time, and the power storage rate satisfy respective predetermined conditions.

3. The battery management system according to claim 2, wherein:
the vehicle data further include a temperature of the in-vehicle battery; and
the collection unit corrects the start-up voltage based on the temperature.

4. The battery management system according to claim 3, wherein the updating unit updates the voltage threshold based on the accumulated start-up voltage when a number of days elapsed since the collection unit started collecting the vehicle data and a number of vehicles for which the vehicle data have been collected satisfy respective predetermined conditions.
